(19) United States
(12) Patent Application Publication
(10) Pub. No.: US 2025/0228117 A1
(43) Pub. Date: Jul. 10, 2025

(54) MASK ASSEMBLY AND METHOD OF MANUFACTURING ORGANIC LIGHT EMITTING DEVICE USING THE SAME

(71) Applicant: Samsung Display Co., Ltd., Yongin-Si (KR)

(72) Inventors: Da Hee JEONG, Yongin-si (KR); Sang Ha PARK, Yongin-si (KR)

(21) Appl. No.: 18/904,109

(22) Filed: Oct. 2, 2024

(30) Foreign Application Priority Data
Jan. 4, 2024 (KR) 10-2024-0001342

(51) Int. Cl. H10K 71/16; C23C 14/04; H10K 59/12

(52) U.S. Cl. CPC H10K 71/166; C23C 14/042; H10K 59/1201

(57) ABSTRACT

According to an embodiment, a mask assembly may include a mask frame, a plurality of first sticks disposed on the mask frame and extending in a direction parallel to first sides of the mask frame, a plurality of second sticks disposed on the first sticks and extending in a direction parallel to second sides of the mask frame, and deposition masks disposed on the second sticks. The second sticks may comprise a first long-side stick disposed adjacent to each of the second sides of the mask frame and a second long-side stick spaced apart from the second sides of the mask frame, the first long-side stick may comprise wing portions extending in the direction parallel to the first sides of the mask frame, and each of the second sides of the mask frame may comprise wing grooves in which the wing portions are seated.

### CROSS-REFERENCE TO RELATED APPLICATIONS

This application claims priority to and the benefit of Korean Patent Application No. 10-2024-0001342, filed on Jan. 4, 2024, in the Korean Intellectual Property Office, the disclosure of which is incorporated herein in its entirety by reference.

### BACKGROUND

### 1. Field

The present disclosure relates to a mask assembly and a method of manufacturing organic light emitting device using the same.

### 2. Description of the Related Art

An organic light emitting display device displays an image using light emitted from organic light emitting elements which are self-luminous elements. An organic light emitting element including a light emitting layer interposed between opposing electrode layers may emit light when excitons generated by recombination of holes and electrons change from an excited state to a ground state.

A deposition process using a deposition mask may be used as a method of manufacturing the electrode layers or the light emitting layer. For example, a deposition mask having openings of substantially the same shape as patterns of a layer to be formed may be aligned on a substrate, and a deposition material may be deposited on the substrate through the openings of the deposition mask to form the patterns of the layer in a desired shape. The deposition mask may be supported by a mask frame and brought into close contact with the substrate.

As organic light emitting display devices become increasingly higher in resolution, electrodes and light emitting layers of organic light emitting elements become smaller in size. Accordingly, a more precise deposition method is required.

### SUMMARY

The present disclosure may provide a mask assembly capable of stably supporting a deposition mask, thereby enhancing the precision of a deposition process, and provide a method of manufacturing organic light emitting device using the mask assembly.

However, the present disclosure is not limited to the one set forth herein. The above and other features of the present disclosure will become more apparent to one of ordinary skill in the art with reference to the detailed description of the present disclosure set forth below.

According to an embodiment of the present disclosure, a mask assembly may comprise a mask frame, a plurality of first sticks disposed on the mask frame and extending in a direction parallel to first sides of the mask frame, a plurality of second sticks disposed on the first sticks and extending in a direction parallel to second sides of the mask frame, and deposition masks disposed on the second sticks. The second sticks may comprise a first long-side stick disposed adjacent to each of the second sides of the mask frame and a second long-side stick spaced apart from the second sides of the mask frame, the first long-side stick may comprise wing portions extending to the direction parallel to the first sides of the mask frame, and each of the second sides of the mask frame may comprise wing grooves in which the wing portions are seated.

Each of the first sides of the mask frame may comprise first grooves in which ends of the second sticks are seated, and each of the second sides of the mask frame may comprise second grooves in which ends of the first sticks are seated.

The wing grooves and the second grooves may overlap each other.

The ends of the first sticks may be seated in the second grooves, and the wing portions are seated in the wing grooves which are placed on the second grooves.

Each of the wing portions may comprise a first wing portion seated in a wing groove and a second wing portion disposed symmetrically to the first wing portion with respect to a direction in which the second sticks extend.

A height of each of the second sticks may be equal to a height of each of the wing grooves.

A width of each of the wing grooves may be equal to or greater than a width of each of the second grooves.

A first length of each of the wing grooves extending from a first inner side surface of the mask frame may be shorter than a second length of each of the first grooves extending from a second inner side surface of the mask frame.

The deposition masks may extend in the direction parallel to the first sides of the mask frame.

Each of the deposition masks may comprise fixing portions positioned at both ends of the deposition mask, at least one deposition pattern portion positioned between the fixing portions and comprising a plurality of pattern openings, and a rib portion positioned around the deposition pattern portion.

According to an embodiment of the present disclosure, a mask assembly may comprise a mask frame, a plurality of second sticks disposed on the mask frame and extending in a direction parallel to second sides of the mask frame, a plurality of first sticks disposed on the second sticks and extending in a direction parallel to first sides of the mask frame, and deposition masks disposed on the first sticks. The second sticks may comprise a first long-side stick disposed adjacent to each of the second sides of the mask frame and a second long-side stick spaced apart from the second sides of the mask frame, the first long-side stick may comprise wing portions extending in the direction parallel to the first sides of the mask frame, and each of the second sides of the mask frame may comprise wing grooves in which the wing portions are seated.

Each of the first sides of the mask frame may comprise first grooves in which ends of the second sticks are seated, and each of the second sides of the mask frame may comprise second grooves in which ends of the first sticks are seated.

The wing grooves and the second grooves may overlap each other.

The ends of the first sticks may be seated in the second grooves, and the wing portions are seated in the wing grooves which are placed under the second grooves.

Each of the wing portions may comprise a first wing portion seated in a wing groove and a second wing portion disposed symmetrically to the first wing portion with respect to a direction in which the second sticks extend.

A height of each of the second sticks may be equal to a height of each of the wing grooves.

A width of each of the wing grooves may be equal to or greater than a width of each of the second grooves.

A first length of each of the wing grooves extending from a first inner side surface of the mask frame may be shorter than a second length of each of the first grooves extending from a second inner side surface of the mask frame.

The deposition masks may extend in the direction parallel to the first sides of the mask frame.

Each of the deposition masks may comprise fixing portions positioned at both ends of the deposition mask, at least one deposition pattern portion positioned between the fixing portions and comprising a plurality of pattern openings, and a rib portion positioned around the deposition pattern portion.

According to an embodiment of the disclosure, a method of manufacturing organic light emitting device may comprise placing a substrate on a surface of a mask assembly, placing a deposition source to face another surface of the mask assembly, and vaporizing a deposition material accommodated in the deposition source, and letting the vaporized deposition material pass through the mask assembly and be deposited on the substrate. The mask assembly may comprise a mask frame, a plurality of first sticks disposed on the mask frame and extending in a direction parallel to first sides of the mask frame, a plurality of second sticks disposed on the first sticks and extending in a direction parallel to second sides of the mask frame, and deposition masks disposed on the second sticks. The second sticks may comprise a first long-side stick disposed adjacent to each of the second sides of the mask frame and a second long-side stick spaced apart from the second sides of the mask frame, the first long-side stick may comprise wing portions extending in the direction parallel to the first sides of the mask frame, and each of the second sides of the mask frame may comprise wing grooves in which the wing portions are seated.

Each of the first sides of the mask frame may comprise first grooves in which ends of the second sticks are seated, and each of the second sides of the mask frame may comprise second grooves in which ends of the first sticks are seated.

The wing grooves and the second grooves may overlap each other.

The ends of the first sticks are seated in the second grooves, and the wing portions are seated in the wing grooves which are placed on the second grooves.

### BRIEF DESCRIPTION OF THE DRAWINGS

The above and other features of the present disclosure will become apparent and more readily appreciated from the following description of the embodiments, taken in conjunction with the accompanying drawings.

FIG. 1 is a plan view of a display device according to an embodiment.

FIG. 2 is a cross-sectional view of the display device according to the embodiment.

FIG. 3 is a plan view of the display device according to the embodiment.

FIG. 4 illustrates the cross-sectional structure of a portion of a display area of a display panel according to an embodiment.

FIG. 5 is a perspective view of a mask assembly according to an embodiment.

FIG. 6 is an exploded perspective view of the mask assembly according to an embodiment.

FIG. 7 is a perspective view of a deposition mask according to an embodiment.

FIG. 8 is a plan view of a mask assembly according to a comparative example.

FIG. 9 illustrates the bending of a long-side stick according to the comparative example.

FIG. 10 is a schematic perspective view of a portion of a mask assembly according to an embodiment.

FIG. 11 is a cross-sectional view of the mask assembly, taken along a line A-A′ of FIG. 10.

FIG. 12 illustrates a length of each wing groove according to an embodiment.

FIG. 13 is an exploded perspective view of a mask assembly according to an embodiment.

FIG. 14 is a schematic perspective view of a portion of the mask assembly according to the embodiment illustrated in FIG. 13.

FIG. 15 is a cross-sectional view of the mask assembly, taken along a line B-B′ of FIG. 14.

FIG. 16 is a schematic view illustrating a deposition process using a mask assembly according to an embodiment.

### DETAILED DESCRIPTION

The present disclosure will now be described more fully hereinafter with reference to the accompanying drawings. This disclosure may, however, be embodied in different forms and should not be construed as limited to the embodiments set forth herein. Rather, these embodiments are merely provided to ensure the completeness of the present disclosure, and will fully convey the scope of the present inventive concept to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present inventive concept. Similarly, the second element could also be termed the first element.

Features of each of various embodiments of the present disclosure may be partially or entirely combined with each other and may technically interwork with each other in various ways. For example, respective embodiments may be implemented independently from each other, or may be implemented together in association with each other.

Hereinafter, embodiments according to the present disclosure will be described with reference to the accompanying drawings.

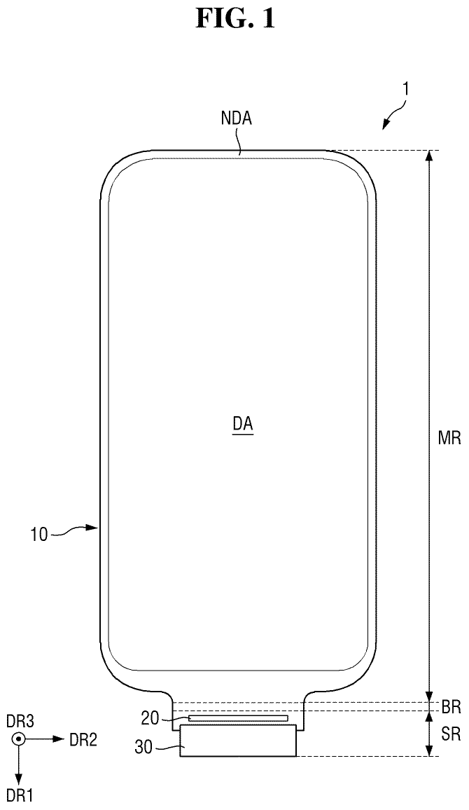

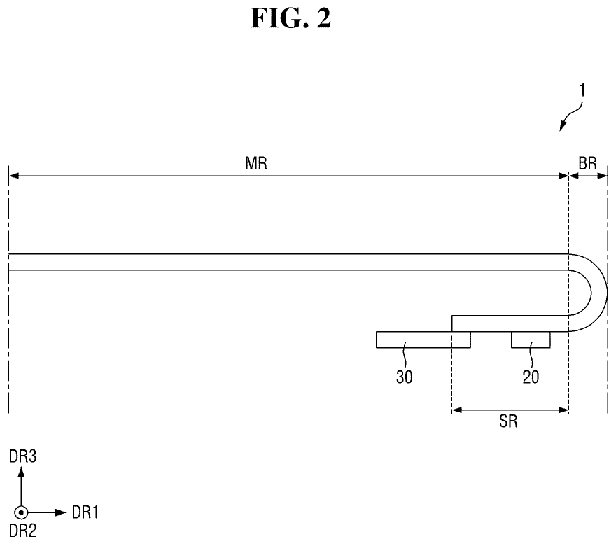

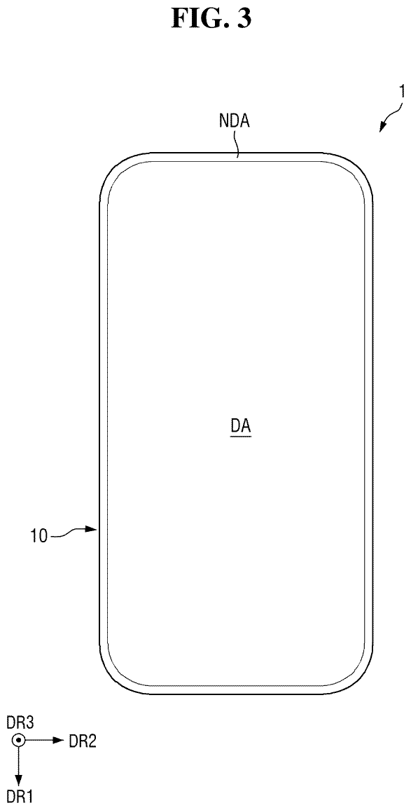

FIG. 1 is a plan view of a display device 1 according to an embodiment. FIG. 2 is a cross-sectional view of the display device 1 according to the embodiment. FIG. 3 is a plan view of the display device 1 according to the embodiment. For example, FIG. 3 illustrates the display device 1 in which a sub-area SR is bent from an end of a bending area BR.

In FIG. 1, up, down, left, and right directions are defined for ease of description. For example, an up-down direction is defined as a first direction DR1 which is a vertical direction or a column direction, a left-right direction is defined as a second direction DR2 which is a horizontal direction or a row direction, and a perpendicular direction is defined as a third direction DR3. The display device 1 may be a device for displaying moving images or still images. The display device 1 may be used in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as to various products such as televisions, notebook computers, monitors, billboards and Internet of things (IoT) devices. The display device 1 may be, for example, an organic light emitting display device, a liquid crystal display device, a plasma display device, a field emission display device, an electrophoretic display device, an electrowetting display device, a quantum dot light emitting display device, or a micro-light emitting diode display device. Hereinafter, the organic light emitting display will be used as an example to explain the display device 1 but embodiments are not limited thereto.

Referring to FIGS. 1 through 3, the display device 1 according to the embodiment may include a display panel 10. The display panel 10 may include a substrate SUB including a flexible polymer material such as polyimide. Accordingly, the display panel 10 can be curved, bent, folded, or rolled.

The display panel 10 may include a main area MR, the bending area BR extending from an end of the main area MR, and the sub-area SR extending from an end of the bending area BR. The bending area BR is an area disposed between the main area MR and the sub-area SR and may be bent with a specified curvature. The sub-area SR may overlap with the main area MR in a thickness direction (e.g., the third direction DR3) as the bending area BR is bent.

The display panel 10 may include a display area DA which displays a screen and a non-display area NDA which does not display the screen. The display area DA may be disposed within the main area MR, the non-display area NDA may be an area other than the display area DA. The main area MR may have a shape generally similar to the external shape of the display device 1 in a plan view. The main area MR may be a flat area located in one plane.

The display area DA of the display panel 10 may be disposed in the center of the main area MR. The display area DA may include a plurality of pixels. The display area DA may have a rectangular shape or a rectangular shape with rounded corners.

In the main area MA, the non-display area NDA may be disposed around the display area DA. The non-display area NDA of the main area MR may be positioned within an area from outer boundaries of the display area DA to edges of the display panel 10. Signal lines or driving circuits for transmitting signals to the display area DA may be disposed in the non-display area NDA of the main area MR.

The bending area BR may be connected to an end of the main area MR. A width of the bending area BR may be smaller than a width of the main area MR. The bending area BR of the display panel 10 may be bent downward with a curvature in the thickness direction, for example, in a direction opposite to a display surface.

The sub-area SR may extend from an end of the bending area BR in a direction parallel to the main area MR. The sub-area SR may overlap with the main area MR in the thickness direction of the display panel 10. The sub-area SR may overlap with the non-display area NDA of an edge of the main area MR and may further overlap with the display area DA of the main area MR.

A driving chip 20 may be disposed on the sub-area SR of the display panel 10. The driving chip 20 may include an integrated circuit which drives the display panel 10. The driving chip 20 may be mounted on the display panel 10 in the sub-area SR.

The driving chip 20 may be attached onto the display panel 10 through an anisotropic conductive film or may be attached onto the display panel 10 through ultrasonic bonding.

A pad unit (not illustrated) may be disposed at an end of the sub-area SR of the display panel 10. The display panel 10 may be connected to a display driving board 30 through the pad unit. The display driving board 30 may be a flexible printed circuit board or film.

A plurality of signal lines may be disposed in the sub-area SR, the bending area BR, and the main area MR. The signal lines may extend from the main area MR to the pad unit of the sub-area SR via the bending area BR.

As described above, the display device 1 according to the embodiment illustrated in FIGS. 1 through 3 may include the sub-area SR in which the pad unit and the driving chip 20 are disposed is placed to face downward in the thickness direction, as the bending area BR of the display panel 10 is bent.

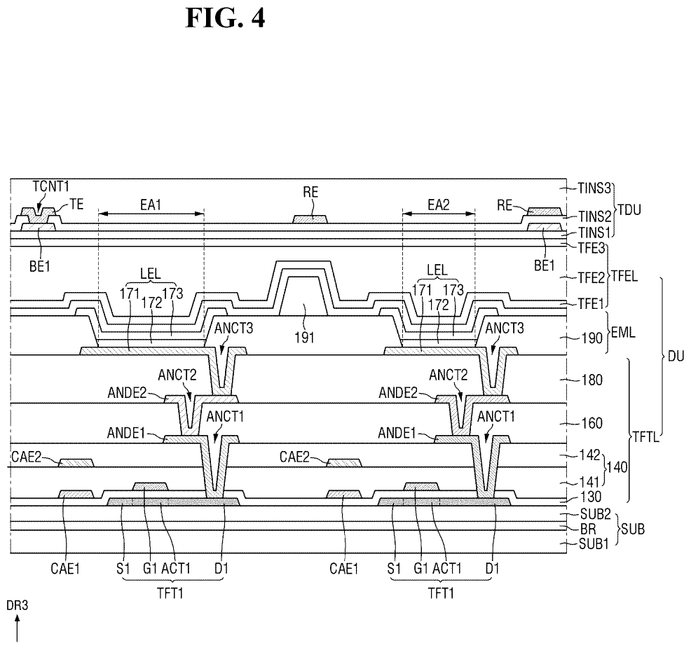

FIG. 4 illustrates the cross-sectional structure of a portion of a display area DA of a display panel 10 according to an embodiment.

In describing FIG. 4, the term “on” may refer to the third direction DR3 which the front of the display panel 10 faces. The front of the display panel 10 may refer to a direction where light emitting elements included in the display panel 10 cmit light to display an image.

Referring to FIG. 4, the display panel 10 uses a flexible substrate SUB as a base substrate. The substrate SUB may include an insulating material such as polymer resin. For example, the substrate SUB may be made of polyimide. Therefore, the substrate SUB can be bent, folded, rolled, etc. The substrate SUB may include multiple layers including a first substrate SUB1, a second substrate SUB2, and a barrier layer BR disposed between the first substrate SUB1 and the second substrate SUB2. For example, the substrate SUB of the display panel 10 includes the first substrate SUB1, the barrier layer BR disposed on the first substrate SUB1, and the second substrate SUB2 disposed on the barrier layer BR. The first substrate SUB1 and the second substrate SUB2 may include a flexible material such as polyimide.

The barrier layer BR is a layer that protects transistors of a thin-film transistor layer TFTL and light emitting layers 172 of a light emitting element layer EML from infiltrating moisture. The barrier layer BR may include a plurality of inorganic layers stacked alternately. For example, the barrier layer BR may be formed as a multilayer structure in which one or more inorganic layers selected from a silicon nitride layer, a silicon oxynitride layer, a silicon oxide layer, a titanium oxide layer, and an aluminum oxide layer are alternately stacked.

The thin-film transistor layer TFTL including thin-film transistors, the light emitting element layer EML including light emitting elements LEL, an encapsulation layer TFEL encapsulating the light emitting elements LEL, and a touch sensing unit TDU may be sequentially stacked on the second substrate SUB2. Although not illustrated, at least some of the layers illustrated in FIG. 4 may not be disposed in a non-display area NDA of the display panel 10. Since the thin-film transistor layer TFTL, the light emitting element layer EML, and the encapsulation layer TFEL perform functions to display images, they may be collectively referred to as, but not limited to, a display unit DU.

Thin-film transistors of a pixel driving circuit which drive each pixel are disposed on the second substrate SUB2. FIG. 4 illustrates the first thin-film transistors TFT1, as an example, among a plurality of thin-film transistors of the pixel driving circuits. For example, each of the first thin-film transistors TFT1 may be a driving transistor in a pixel driving circuit.

Each of the first thin-film transistors TFT1 may include a first active layer ACT1 and a first gate electrode G1. The first active layer ACT1 may include polycrystalline silicon, monocrystalline silicon, low-temperature polycrystalline silicon, amorphous silicon, or an oxide semiconductor.

The first active layer ACT1 may include a first source region S1 and a first drain region D1. A first channel region CHAI may be a region overlapped by the first gate electrode G1 in the third direction DR3 which is the thickness direction of the substrate SUB. The first source region S1 may be positioned in a first side of the first active layer ACT1, and the first drain region D1 may be positioned in a second side of the first active layer ACT1, which is the opposite side to the first side of the first active layer ACT1. The first source region S1 and the first drain region D1 may be regions not overlapped by the first gate electrode G1 in the third direction DR3. The first source region S1 and the first drain region D1 may be regions having conductivity by doping a silicon semiconductor or an oxide semiconductor with ions or impurities.

A gate insulating layer 130 may be disposed on the first active layers ACT1 of the first thin-film transistors TFT1. The gate insulating layer 130 may include an inorganic layer such as a silicon nitride layer, a silicon oxynitride layer, a silicon oxide layer, a titanium oxide layer, or an aluminum oxide layer.

The first gate electrodes G1 of the first thin-film transistors TFT1 and first capacitor electrodes CAE1 may be disposed on the gate insulating layer 130. The first gate electrodes G1 may overlap the first active layers ACT1 in the third direction DR3. Although the gate electrodes G1 and the first capacitor electrodes CAE1 are spaced apart from each other in FIG. 4, they may also be connected to each other. Each of the gate electrodes G1 and the first capacitor electrodes CAE1 may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

Interlayer insulating layers 140 may be disposed on the first gate electrodes G1 of the first thin-film transistors TFT1 and the first capacitor electrodes CAE1. Specifically, a first interlayer insulating layer 141 may be disposed on the first gate electrodes G1 of the first thin-film transistors TFT1 and the first capacitor electrodes CAE1. The first interlayer insulating layer 141 may include an inorganic layer such as a silicon nitride layer, a silicon oxynitride layer, a silicon oxide layer, a titanium oxide layer, or an aluminum oxide layer. The first interlayer insulating layer 141 may be composed of a plurality of inorganic layers.

Second capacitor electrodes CAE2 may be disposed on the first interlayer insulating layer 141. The second capacitor electrodes CAE2 may overlap the first capacitor electrodes CAE1 of the first thin-film transistors TFT1 in the third direction DR3. When the first capacitor electrodes CAE1 are connected to the first gate electrodes G1, the second capacitor electrodes CAE2 may overlap the first gate electrodes G1 in the third direction DR3. Since the first interlayer insulating layer 141 has a predetermined dielectric constant, capacitors may be formed by the first capacitor electrodes CAE1, the second capacitor electrodes CAE2, and the first interlayer insulating layer 141 disposed between the first capacitor electrode CAE1 and the second capacitor electrode CAE2. Each of the second capacitor electrodes CAE2 may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

A second interlayer insulating layer 142 may be disposed on the second capacitor electrodes CAE2. The second interlayer insulating layer 142 may include an inorganic layer such as a silicon nitride layer, a silicon oxynitride layer, a silicon oxide layer, a titanium oxide layer, or an aluminum oxide layer. The second interlayer insulating layer 142 may be composed of a plurality of inorganic layers.

First anode connection electrodes ANDE1 may be disposed on the second interlayer insulating layer 142. The first anode connection electrodes ANDE1 may be connected to the first drain regions D1 of the first thin-film transistors TFT1 through first connection contact holes ANCT1 extending through the gate insulating layer 130, the first interlayer insulating layer 141, and the second interlayer insulating layer 142. Each of the first anode connection electrodes ANDE1 may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

A first planarization layer 160 may be disposed on the first anode connection electrodes ANDE1 to smooth out irregularities caused by the first thin-film transistors TFT1. The first planarization layer 160 may include an organic layer such as acryl resin, epoxy resin, phenolic resin, polyamide resin, or polyimide resin.

Second anode connection electrodes ANDE2 may be disposed on the first planarization layer 160. The second anode connection electrodes ANDE2 may be connected to the first anode connection electrodes ANDE1 through second connection contact holes ANCT2 extending through the first planarization layer 160. Each of the second anode connection electrodes ANDE2 may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

A second planarization layer 180 may be disposed on the second anode connection electrodes ANDE2. The second planarization layer 180 may include an organic layer such as acryl resin, epoxy resin, phenolic resin, polyamide resin, or polyimide resin.

The light emitting elements LEL and a bank 190 may be disposed on the second planarization layer 180. Each of the light emitting elements LEL includes a pixel electrode 171, a light emitting layer 172, and a common electrode 173.

The pixel electrode 171 may be disposed on the second planarization layer 180. The pixel electrode 171 may be connected to each of the second anode connection electrodes ANDE2 through a third connection contact hole ANCT3 extending through the second planarization layer 180.

In a top emission structure in which light is emitted from the light emitting layer 172 toward the common electrode 173, the pixel electrode 171 may include a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The bank 190 may be formed on the second planarization layer 180 to separate the pixel electrodes 171 so as to define an emission area, for example, a light emitting portion of each pixel. The light emitting portion (e.g., EA1, EA2) is an area in which the pixel electrode 171, the light emitting layer 172, and the common electrode 173 are sequentially disposed so that holes from the pixel electrode 171 and electrons from the common electrode 173 are recombined in the light emitting layer 172 to emit light.

In FIG. 4, the bank 190 defines a first light emitting portion EA1 of a first pixel and a second light emitting portion EA2 of a second pixel which are adjacent to each other. The bank 190 may cover edges of the pixel electrodes 171. The bank 190 may include an organic layer such as acryl resin, epoxy resin, phenolic resin, polyamide resin, or polyimide resin. The bank 190 may also be referred to as a pixel defining layer (PDL). Although not illustrated, the display panel 10 may comprise a plurality of pixels including first pixels, second pixels, and third pixels. For example, each of the first pixels may include a first light emitting portion that emits light of a first color, each of the second pixels may include a second light emitting portion that emits light of a second color, and each of the third pixels may include a third light emitting portion that emits light of a third color. According to an embodiment, the pixels may further include fourth pixels, and each of the fourth pixels may include a fourth light emitting portion that emits light of a fourth color.

The light emitting layer 172 may be disposed on the pixel electrode 171 and the bank 190. The light emitting layer 172 may include an organic material to emit light of a predetermined color. The light emitting layer 172 may further include a hole transporting layer, an organic material layer, and an electron transporting layer.

The common electrode 173 may be disposed on the light emitting layer 172. The common electrode 173 may cover the light emitting layer 172. The common electrode 173 may be a common layer commonly disposed in the first light emitting portion EA1, the second light emitting portion EA2, and a third light emitting portion (not illustrated). A capping layer may be formed on the common electrode 173.

In the top emission structure, the common electrode 173 may include a transparent conductive material (TCO) that can transmit light, such as indium tin oxide (ITO) or indium zinc oxide (IZO), or may include a semi-transmissive conductive material such as magnesium (Mg), silver (Ag) or an alloy of Mg and Ag. If the common electrode 173 includes a semi-transmissive conductive material, light output efficiency may be increased by a microcavity.

A spacer 191 may be disposed on the bank 190. The spacer 191 may support a mask during a process of manufacturing the light emitting layers 172. The spacer 191 may include an organic layer such as acryl resin, epoxy resin, phenolic resin, polyamide resin, or polyimide resin.

The encapsulation layer TFEL may be disposed on the common electrodes 173. The encapsulation layer TFEL may include at least one inorganic layer to prevent oxygen or moisture from permeating into the light emitting element layer EML. In addition, the encapsulation layer TFEL may include at least one organic layer to protect the light emitting element layer EML from foreign substances such as dust. For example, the encapsulation layer TFEL may include a first encapsulating inorganic layer TFE1, an encapsulating organic layer TFE2, and a second encapsulating inorganic layer TFE3.

The first encapsulating inorganic layer TFE1 may be disposed on the common electrodes 173, the encapsulating organic layer TFE2 may be disposed on the first encapsulating inorganic layer TFE1, and the second encapsulating inorganic layer TFE3 may be disposed on the encapsulating organic layer TFE2. Each of the first encapsulating inorganic layer TFEL and the second encapsulating inorganic layer TFE3 may be formed as a multilayer structure in which one or more inorganic layers selected from a silicon nitride layer, a silicon oxynitride layer, a silicon oxide layer, a titanium oxide layer, and an aluminum oxide layer are alternately stacked. The encapsulating organic layer TFE2 may be an organic layer such as acryl resin, epoxy resin, phenolic resin, polyamide resin, or polyimide resin.

The touch sensing unit TDU may be disposed on the encapsulation layer TFEL. The touch sensing unit TDU may be a mutual capacitive touch sensor or a self-capacitive touch sensor. Although FIG. 4 illustrates a mutual capacitive touch sensor, the present disclosure is not limited thereto. The touch sensing unit TDU includes a first touch insulating layer TINS1, connection electrodes BE1, a second touch insulating layer TINS2, driving electrodes TE, sensing electrodes RE, and a third touch insulating layer TINS3.

The first touch insulating layer TINS1 may include an inorganic layer such as a silicon nitride layer, a silicon oxynitride layer, a silicon oxide layer, a titanium oxide layer, or an aluminum oxide layer.

The connection electrodes BE1 may be disposed on the first touch insulating layer TINS1. Each of the connection electrodes BE1 may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

The second touch insulating layer TINS2 is disposed on the connection electrodes BE1. The second touch insulating layer TINS2 may include an inorganic layer such as a silicon nitride layer, a silicon oxynitride layer, a silicon oxide layer, a titanium oxide layer, or an aluminum oxide layer. In some embodiments, the second touch insulating layer TINS2 may include an organic layer such as acryl resin, epoxy resin, phenolic resin, polyamide resin, or polyimide resin.

The driving electrodes TE and the sensing electrodes RE may be disposed on the second touch insulating layer TINS2. Each of the driving electrodes TE and the sensing electrodes RE may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

The driving electrodes TE and the sensing electrodes RE may overlap the connection electrodes BE1 in the third direction DR3. Each of the driving electrodes TE may be connected to a connection electrode BE1 through a touch contact hole TCNT1 extending through the second touch insulating layer TINS2.

The third touch insulating layer TINS3 is formed on the driving electrodes TE and the sensing electrodes RE. The third touch insulating layer TINS3 may smooth out irregularities caused by the driving electrodes TE, the sensing electrodes RE, and the connection electrodes BE1. The third touch insulating layer TINS3 may include an organic layer such as acryl resin, epoxy resin, phenolic resin, polyamide resin, or polyimide resin.

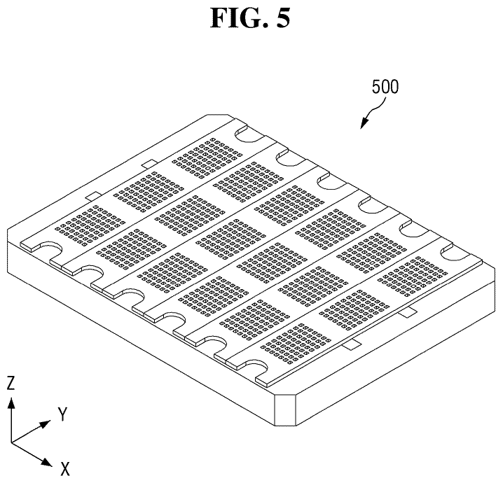

A mask assembly 500 according to an embodiment will now be described with reference to FIGS. 5 through 16. The mask assembly 500 may be used in a process of depositing the light emitting layers 172 of the display panel 10 described with reference to FIG. 4.

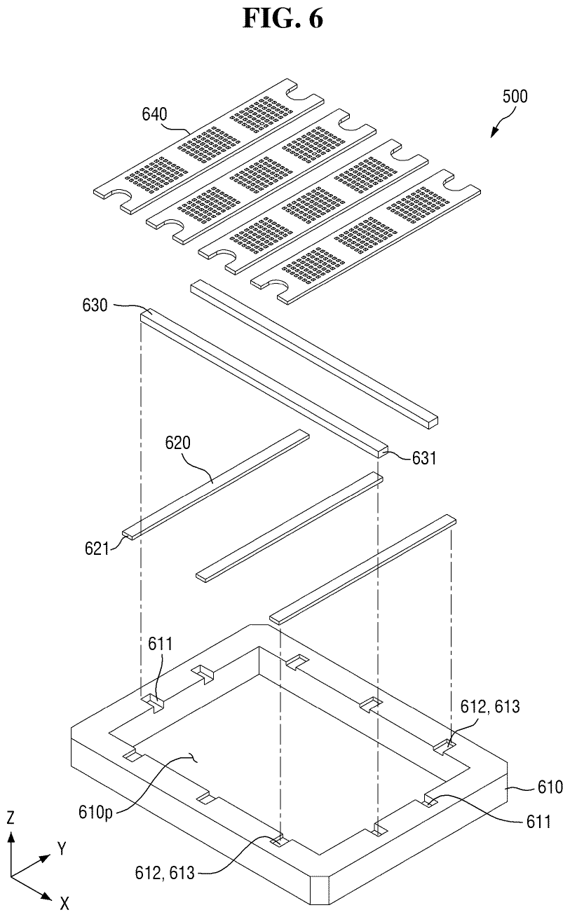

FIG. 5 is a perspective view of a mask assembly 500 according to an embodiment. FIG. 6 is an exploded perspective view of the mask assembly 500 according to the embodiment.

Referring to FIGS. 5 and 6, the mask assembly 500 according to the embodiment of the present disclosure includes a mask frame 610, a plurality of short-side sticks 620 disposed on the mask frame 610 and extending in a direction parallel to short sides of the mask frame 610, a plurality of long-side sticks 630 disposed on the short-side sticks 620 and extending in a direction parallel to long sides of the mask frame 610, and deposition masks 640 disposed on the long-side sticks 630.

In the present disclosure, the short-side sticks 620 may be referred to as “first sticks,” and the long-side sticks 630 may be referred to as “second sticks.” In another embodiment, the short-side sticks may be referred to as the “second sticks,” and the long-side sticks may be referred to as the “first sticks.”

The mask frame 610 may be coupled to the deposition masks 640 to support the deposition masks 640. The mask frame 610 may have a predetermined thickness in a third direction Z to stably support the deposition masks 640 and the like.

The mask frame 610 may be shaped like a quadrangular band including a pair of long sides which may be referred to as “first sides”, a pair of short sides which may be referred to as “second sides”, and a frame opening 610p formed in the center. For example, the pair of long sides may extend in a first direction X and face each other in a second direction Y, and the pair of short sides may extend in the second direction Y and face each other in the first direction X.

The frame opening 610p may be substantially rectangular in a plan view. The frame opening 610p may provide a path through which a deposition material passes.

According to an embodiment, the mask frame 610 may also be shaped like a quadrangular band in which two pairs of sides have the same length, and the frame opening 610p may be square in a plan view.

The mask frame 610 may include a material with high rigidity, for example, a metal such as stainless steel.

The mask frame 610 may be coupled to the long-side sticks 630 and the short-side sticks 620 to support the long-side sticks 630 and the short-side sticks 620. In an exemplary embodiment, the mask frame 610 includes one or more grooves 611, 612 and 613 to at least partially accommodate the long-side sticks 630 and the short-side sticks 620.

The short-side sticks 620 are disposed on a surface (upper surface in the drawings) of the mask frame 610. The short-side sticks 620 may be support members configured to additionally support the deposition masks 640 disposed thereon, together with the long-side sticks 630.

Surfaces (upper surfaces in the drawings) of the short-side sticks 620 may be flat surfaces having a predetermined area to effectively support the deposition masks 640 by contacting the deposition masks 640 thereon. In an exemplary embodiment, the cross-sectional shape of each of the short-side sticks 620 may be a rectangle with longer lengths on an upper side (i.e., a first surface) and a lower side (i.e., a second surface), and shorter lengths on both lateral sides.

The short-side sticks 620 may extend in the second direction Y to cross the long-side sticks 630 and traverse the frame opening 610p. For example, each of the short-side sticks 620 may be roughly shaped like a bar whose length is greater than width.

The long-side sticks 630 are disposed on the surfaces (upper surfaces in the drawings) of the short-side sticks 620. The long-side sticks 630 may be support members configured to additionally support the deposition masks 640 disposed thereon.

Surfaces (upper surfaces in the drawings) of the long-side sticks 630 may be flat surfaces having a predetermined area to effectively support the deposition masks 640 by contacting the deposition masks 640 thereon. In an exemplary embodiment, the cross-sectional shape of each of the long-side sticks 630 may be a rectangle with longer lengths on an upper side (i.e., a first surface) and a lower side (i.e., a second surface), and shorter lengths on both lateral sides.

The long-side sticks 630 may extend in the first direction X to traverse the frame opening 610p. For example, each of the long-side sticks 630 may be roughly shaped like a bar whose length (e.g., length in the first direction X) is greater than width (e.g., width in the second direction Y).

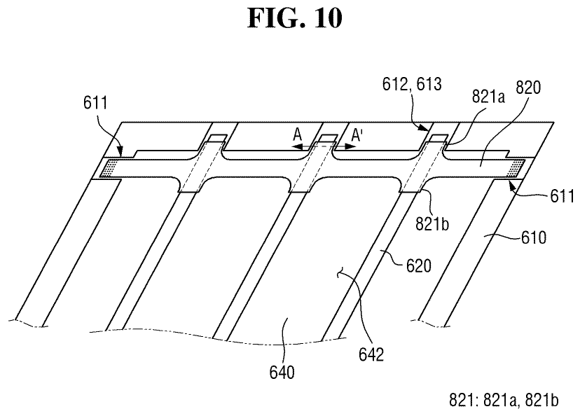

The long-side sticks 630 may extend in the first direction X, and both ends 631 thereof may be inserted into first grooves (e.g., long-side stick grooves) 611 which are positioned at the short sides of the mask frame 610. The long-side sticks 630 may not overlap deposition pattern portions 642 of the deposition masks 640. For example, the long-side sticks 630 may overlap rib portions 643 of the deposition masks 640 which will be described later. To prevent deformation due to differences in thermal expansion characteristics during a deposition process, the mask frame 610 and the long-side sticks 630 may include the same material. The second grooves 612 of the mask frame 610 may overlap wing grooves (e.g., third grooves) 613 for accommodating wing portions 821a (see FIG. 10) of first long-side sticks 820 (see FIG. 10) disposed at outermost positions among the long-side sticks 630.

In an embodiment, as the mask frame 610 includes the long sides extending in the first direction X and the short sides extending in the second direction Y, the short-side sticks 620 may be shorter than the long-side sticks 630. As will be described later, the short-side sticks 620 may extend in the second direction Y, and both ends 621 thereof may be inserted into second grooves (e.g., short-side stick grooves) 612 which are positioned at the long sides of the mask frame 610. Like the long-side sticks 630, the short-side sticks 620 may not overlap the deposition pattern portions 642 of the deposition masks 640. For example, each of the short-side sticks 620 may overlap with the boundaries of two adjacent deposition masks 640. The short-side sticks 620 may include the same material as the long-side sticks 630.

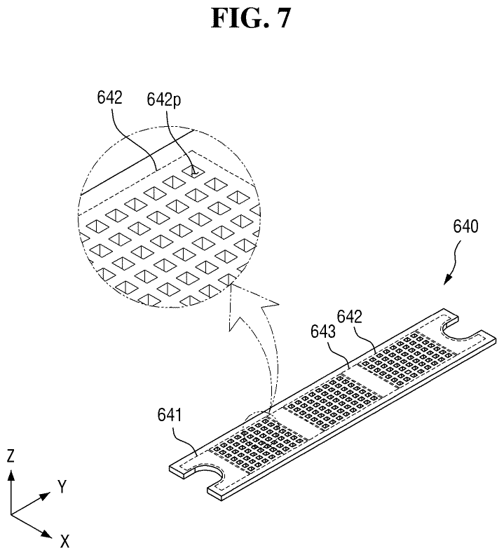

FIG. 7 is a perspective view of a deposition mask 640 according to an embodiment.

The deposition mask 640 extends in the direction parallel to the short sides of the mask frame 610. The deposition mask 640 may be disposed on surfaces of the long-side sticks 630 and the short-side sticks 620. The deposition mask 640 has a first surface (upper surface in the drawing) and a second surface (bottom surface in the drawing). The first surface may be a surface that contacts a substrate (not illustrated) during a deposition process, and the second surface may be a surface opposite the first surface and a surface to which a deposition material is applied. The second surface of the deposition mask 640 may contact one or more of the mask frame 610, the long-side sticks 630, and the short-side sticks 620.

A length (e.g., a length in the second direction Y) of the deposition mask 640 may be greater than a width (e.g., a width in the first direction X) of the deposition mask 640. The deposition mask 640 may include a plurality of masks extending in the first direction X and disposed adjacent to each other in the second direction Y. In an embodiment, the deposition mask 640 may be an integrated mask having a planar area covering the frame opening 610p. In an exemplary embodiment, the deposition mask 640 may be a fine metal mask including a metal material. The deposition mask 640 may include metal such as stainless steel, nickel, cobalt, or an alloy thereof. In some embodiments, the deposition mask 640 may be magnetic.

The deposition mask 640 may include fixing portions 641 positioned at both ends of the deposition mask 640 in a longitudinal direction (i.e., the second direction Y), a plurality of deposition pattern portions 642 positioned closer to the center than the fixing portions 641, and a rib portion 643 positioned between two adjacent deposition pattern portions 642.

The fixing portions 641 are portions that contact and combine with the mask frame 610. For example, the fixing portions 641 may be coupled to the mask frame 610 by welding. The welding method is not particularly limited, but examples of the welding method may include laser welding and resistance heating welding.

Each of the deposition pattern portions 642 is a portion in which a plurality of pattern openings 642p are formed to provide a path for the deposition material to pass through. The deposition pattern portions 642 may be spaced apart from each other in the longitudinal direction (i.e., the second direction Y) of the deposition mask 640.

The rib portion 643 is defined between the deposition pattern portions 642 adjacent to each other in the second direction Y. That is, the rib portion 643 may be a portion that separates the deposition pattern portions 642 adjacent to each other in the second direction Y. Since the rib portion 643 does not have the pattern openings 642p, it can block a deposition material from passing therethrough. In an exemplary embodiment, the rib portion 643 may overlap the long-side sticks 630 extending in the first direction X.

The pattern openings 642p are openings that extend through a first surface (i.e., an upper surface) and a second surface (i.e., a lower surface) of the deposition mask 640. The pattern openings 642p of the deposition mask 640 aligned on the substrate (not illustrated) may expose deposition target areas of the substrate. That is, the pattern openings 642p may have substantially the same planar shape as deposition patterns to be formed. In FIG. 1 and the like, the pattern openings 642p are shaped like dots spaced apart from each other in the first direction X and the second direction Y in a plan view and are arranged in a roughly matrix shape to form each of the deposition pattern portions 642. However, the present disclosure is not limited thereto, and the pattern openings 642p may also be shaped like slits extending in the first direction X or the second direction Y in a plan view.

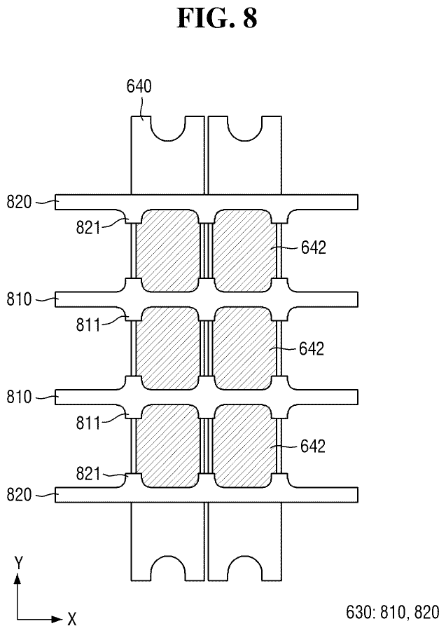

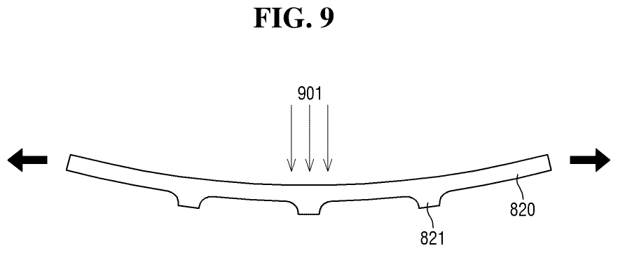

FIG. 8 is a plan view of a mask assembly 500 according to a comparative example. FIG. 9 illustrates the bending of a long-side stick 630 according to the comparative example.

Referring to FIGS. 8 and 9, the mask assembly 500 according to the comparative example includes a plurality of long-side sticks 630 coupled to a mask frame 610. The long-side sticks 630 may extend parallel to long sides of the mask frame 610 and partially mask deposition pattern portions 642 of each deposition mask. For example, four corners of each deposition pattern portion 642 may be rounded with a specified curvature in a plan view.

Each of the long-side sticks 630 may include wing portions 811 or 821 extending in a short-side direction of the mask frame 610 to mask the corners of each deposition pattern portion 642 and form the rounded shape. The long-side sticks 630 may include first long-side sticks 820 disposed adjacent to the long sides of the mask frame 610 and second long-side sticks 810 spaced apart from the long sides of the mask frame 610. For example, the first long-side sticks 820 may be outermost long-side sticks 630 among the long-side sticks 630. The second long-side sticks 810 may be long-side sticks 630 disposed between the first long-side sticks 820.

In the present disclosure, wing portions may also be referred to by terms such as “extension portions” or “protrusion portions.”

According to the comparative example, since the first long-side sticks 820 are disposed at outermost positions, they include asymmetrical wing portions 821. For example, each of the first long-side sticks 820 includes wing portions 821 (e.g., asymmetrical wing portions) which protrude in only one direction. On the other hand, the second long-side sticks 810 disposed between the first long-side sticks 820 include symmetrical wing portions 811. For example, each of the second long-side sticks 810 includes wing portions 811 (e.g., symmetrical wing portions) which protrude in both directions (e.g., up and down in FIG. 8). The second long-side sticks 810 are symmetrical in a plan view because the wing portions 811 protrude in both directions.

According to the comparative example, the mask assembly 500 may experience bending of the first long-side sticks 820 due to the inclusion of the asymmetrical wing portions 821 in the first long-side sticks 820. For example, when the first long-side sticks 820 are combined with the mask frame 610, the tensile force applied to the first long-side sticks 820 causes the first long-side sticks 820 to bend in a specific direction (e.g., 901 in FIG. 9). The bending of the first long-side sticks 820 occurs because the wing portions 821 included in the first long-side sticks 820 are asymmetrical. This bending of the first long-side sticks 820 may cause defects in a deposition process.

In an embodiment of the present disclosure, the first long-side sticks 820 include symmetrical wing portions 821 to prevent the bending of the first long-side sticks 820 as happened in the comparative example. In addition, the mask frame 610 may include the wing grooves 613 (e.g., the third grooves) which accommodates the wing portions 821 of the first long-side sticks 820. The wing grooves 613 of the mask frame 610 overlap the second grooves 612 where the short-side sticks 620 may be accommodated. Therefore, a surface of the mask frame 610 where the ends of each deposition mask are welded does not have a height difference even when the wing portions 821 of the long-side sticks 630 are placed on the surface of the mask frame 610. The embodiment of the present disclosure can improve the reliability of a deposition process by preventing defects such as tearing of the deposition masks.

Mask assembly 500 according to embodiments of the present disclosure will now be described in more detail with reference to FIGS. 10 through 16.

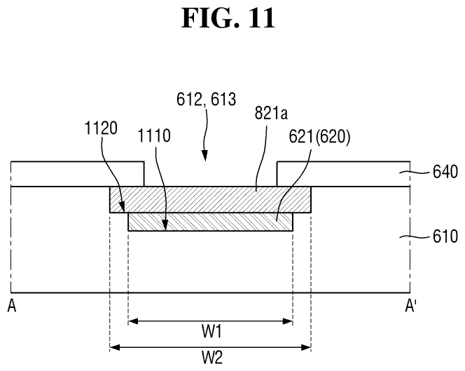

FIG. 10 is a schematic perspective view of a portion of a mask assembly 500 according to an embodiment. FIG. 11 is a cross-sectional view of the mask assembly 500, taken along a line A-A′ of FIG. 10.

The embodiment of the present disclosure illustrated in FIGS. 10 and 11 is different from the comparative example illustrated in FIG. 8 in that first long-side sticks 820 disposed adjacent to long sides of a mask frame 610 include symmetrical wing portions 821, and wing grooves 613 (e.g., third grooves) are formed in the mask frame 610 so that the wing portions 821 of the first long-side sticks 820 can be inserted into the wing grooves 613. Therefore, only differences of the embodiment of the present disclosure from the comparative example illustrated in FIG. 8 will be described below.

Referring to FIGS. 6, 10 and 11, the mask assembly 500 includes a plurality of long-side sticks 630 coupled to the mask frame 610. The long-side sticks 630 may extend parallel to the long sides of the mask frame 610 in a long-side direction of the mask frame 610 (e.g., X direction in FIG. 6) and may partially mask deposition pattern portions 642 of deposition masks. For example, four corners of each deposition pattern portion 642 may be rounded with a specified curvature in a plan view.

The long-side sticks 630 may include wing portions 811 and 821 extending in a short-side direction of the mask frame 610 (e.g., Y direction in FIG. 6) to mask the corners of each deposition pattern portion 642 in a rounded shape. The long-side sticks 630 may include first long-side sticks 820 disposed adjacent to the long sides of the mask frame 610 and second long-side sticks 810 spaced apart from the long sides of the mask frame 610. For example, the first long-side sticks 820 may be outermost long-side sticks 630 among the long-side sticks 630. The second long-side sticks 810 may be long-side sticks 630 disposed between the first long-side sticks 820.

According to an embodiment, each of the first long-side sticks 820 includes symmetrical wing portions 821. For example, each of the first long-side sticks 820 includes wing portions 821 protruding in both directions. The second long-side sticks 810 are disposed between the first long-side sticks 820 and include symmetrical wing portions 811. The first long-side sticks 820 and the second long-side sticks 810 are symmetrical in a plan view because their wing portions 811 and 821 protrude in both directions.

Each of the long sides of the mask frame 610 includes the wing grooves 613 which accommodate the wing portions 821 of a first long-side stick 820. Each of the wing portions 821 includes a first wing portion 821a seated in the wing groove 613 and a second wing portion 821b which is symmetrical to the first wing portion 821a with respect to a direction in which the long-side sticks 630 extend. Each of the long sides of the mask frame 610 may include the wing grooves 613 so that the first wing portions 821a among the first wing portions 821a and the second wing portions 821b of a first long-side stick 820 can be inserted into the wing grooves 613.

Each of the long sides of the mask frame 610 includes second grooves 612 (e.g., short-side stick grooves) which accommodate ends of short-side sticks 620. The wing grooves 613 and the second grooves 612 overlap each other. For example, the wing grooves 613 where the first wing portions 821a of each first long-side stick 820 are seated may be positioned on the second grooves 612 where the ends 621 (see FIG. 6) of the short-side sticks 620 are seated.

The ends 621 (see FIG. 6) of the short-side sticks 620 are seated in the second grooves 612, and the wing portions 821 (i.e., the first wing portions 821a) are seated in the wing grooves 613 positioned on the second grooves 612. For example, the height of a bottom surface 1110 of each second groove 612 may be lower than the height of a bottom surface 1120 of each wing groove 613.

A width W2 of each wing groove 613 is greater than a width W1 of each second groove 612.

First grooves 611 (e.g., long-side stick grooves) are disposed on short sides of the mask frame 610. A height of each first groove 611 is equal to a height of each wing groove 613.

According to an embodiment, the long-side sticks 630 may be inserted into the first grooves 611 and coupled to the mask frame 610 by a welding process. On the other hand, the first wing portions 821a of the long-side sticks 630 may be inserted into the wing grooves 613, but does not experience a welding process. The welding process is not performed on the first wing portions 821a of the long-side sticks 630 to prevent distortion of the long-side sticks 630 due to the welding process. For example, if the first wing portions 821a are welded, there may be a lift of the unwelded second wing portions 821b.

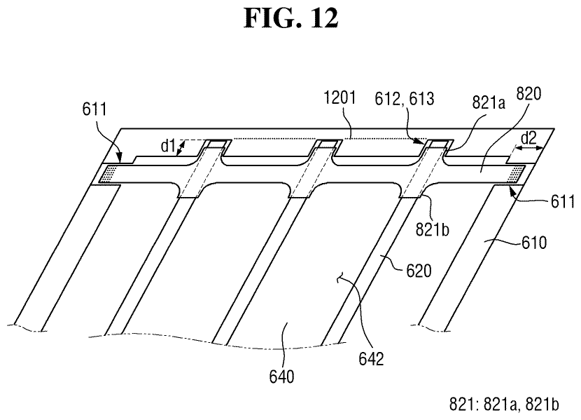

FIG. 12 illustrates a length of each wing groove 613 according to an embodiment.

The embodiment of FIG. 12 is different from the embodiment of FIG. 10 in that a length d1 of each wing groove 613 is different from a length d2 of each first groove 611. The length d1 of each wing groove 613 refers to a length by which the wing groove 613 extends from a first inner side surface of a mask frame 610. In addition, the length d2 of each first groove 611 refers to a length by which the first groove 611 extends from a second inner side surface of the mask frame 610. The length d1 of each wing groove 613 may refer to a length by which the wing groove 613 overlaps the mask frame 610. In addition, the length d2 of each first groove 611 may refer to a length by which the first groove 611 overlaps the mask frame 610.

In the embodiment of FIG. 10, the length d1 of each wing groove 613 may be equal to the length d2 of each first groove 611. On the other hand, in the embodiment of FIG. 12, the length d1 of each wing groove 613 is shorter than the length d2 of each first groove 611. For example, a first length d1 of each wing groove 613 extending from the first inner side surface of the mask frame 610 is shorter than a second length d2 of each first groove 611 extending from the second inner side surface of the mask frame 610.

In the embodiment of the present disclosure, since the length d1 of each wing groove 613 is shorter than the length d2 of each first groove 611, a space to which a deposition mask is welded can be easily secured on the long sides of the mask frame 610. For example, in FIG. 12, a dotted line 1201 indicates an area of the mask frame 610 to which a deposition mask is welded, and a welded portion of the deposition mask may be an area secured by relatively shortening the length d1 of each wing groove 613, measured from an inner side surface of the mask frame 610.

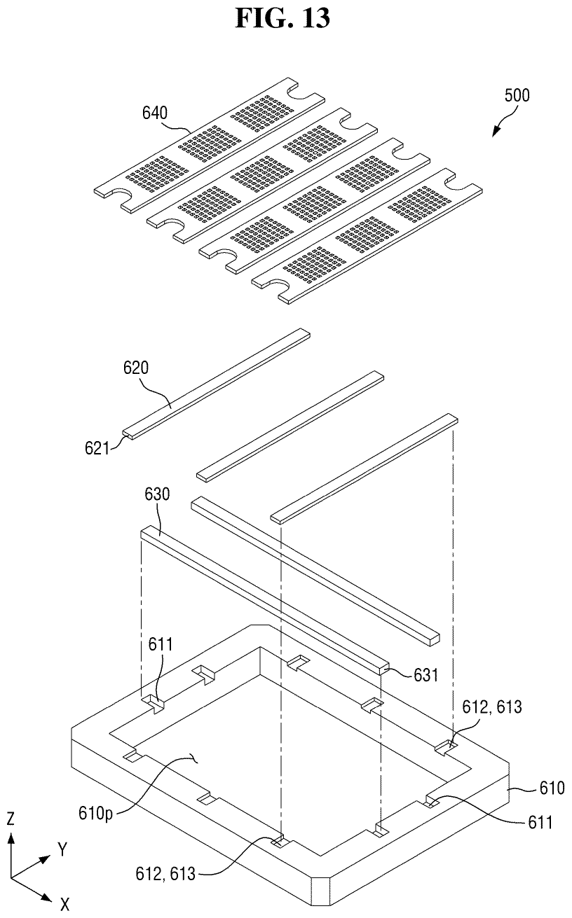

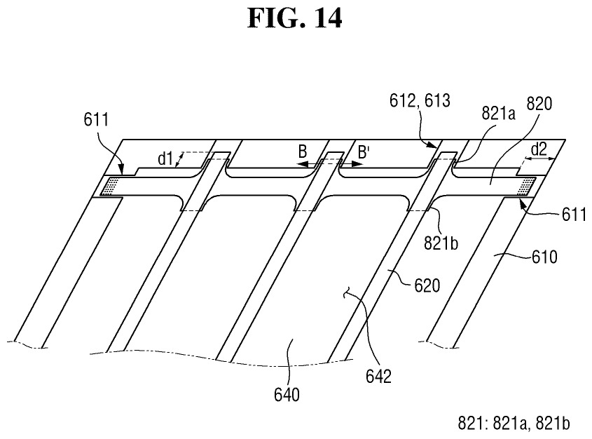

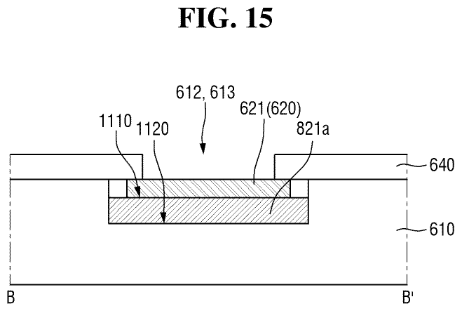

FIG. 13 is an exploded perspective view of a mask assembly 500 according to an embodiment. FIG. 14 is a schematic perspective view of a portion of the mask assembly 500 according to the embodiment illustrated in FIG. 13. FIG. 15 is a cross-sectional view of the mask assembly 500, taken along a line B-B′ of FIG. 14.

The embodiment of FIGS. 13 through 15 is different from the embodiments of the present disclosure described in FIGS. 6 through 12 in that short-side sticks 620 are disposed on long-side sticks 630. Therefore, only novel features of the embodiment of FIGS. 13 through 15 will be described below. A description of features not described in FIGS. 13 through 15 will be replaced with the description of the embodiments with reference to FIGS. 6 through 12.

Referring to FIGS. 13 through 15, the mask assembly 500 according to the embodiment includes a mask frame 610, a plurality of long-side sticks 630 disposed on the mask frame 610 and extending in a direction parallel to long sides of the mask frame 610, a plurality of short-side sticks 620 disposed on the long-side sticks 630 and extending in a direction parallel to short sides of the mask frame 610, and deposition masks disposed on the short-side sticks 620.

The long-side sticks 630 include first long-side sticks 820 disposed adjacent to the long sides of the mask frame 610 and second long-side sticks 810 spaced apart from the long sides of the mask frame 610.

Each of the first long-side sticks 820 includes wing portions 821 extending in a short-side direction of the mask frame 610 to partially mask openings of the deposition masks. Each of the long sides of the mask frame 610 includes wing grooves 613 in which some 821 of the wing portions 811 and 821 are seated.

Each of the short sides of the mask frame 610 includes first grooves 611 in which ends of the long-side sticks 630 are seated. Each of the long sides of the mask frame 610 includes second grooves 612 in which ends of the short-side sticks 620 are seated.

The wing grooves 613 and the second grooves 612 positioned at the long sides of the mask frame 610 overlap each other. A width of each wing groove 613 may be substantially equal to a width of each second groove 612. For example, the wing grooves 613 and the second grooves 612 may be substantially integrally formed with each other.

First wing portions 821a of the first long-side sticks 820 may be seated in the wing grooves 613 and the second grooves 612, and ends 621 (see FIG. 13) of the short-side sticks 620 may be seated on the first wing portions 821a of the first long-side sticks 820.

A height of each first groove 611 is equal to a height of each wing groove 613. Here, the height of each first groove 611 refers to a depth from an upper surface of the mask frame 610 to a bottom surface of the first groove 611. The height of each wing groove 613 refers to a depth from a bottom surface 1110 of the second grooves 612, in which the ends 621 of the short-side sticks 620 are seated, to a bottom surface 1120 of the wing groove 613.

A first length d1 of each wing groove 613 extending from a first inner side surface of the mask frame 610 is shorter than a second length d2 of each first groove 611 extending from a second inner side surface of the mask frame 610. The length d1 of each wing groove 613 may refer to a length by which the wing groove 613 overlaps the mask frame 610. In addition, the length d2 of each first groove 611 may refer to a length by which the first groove 611 overlaps the mask frame 610.

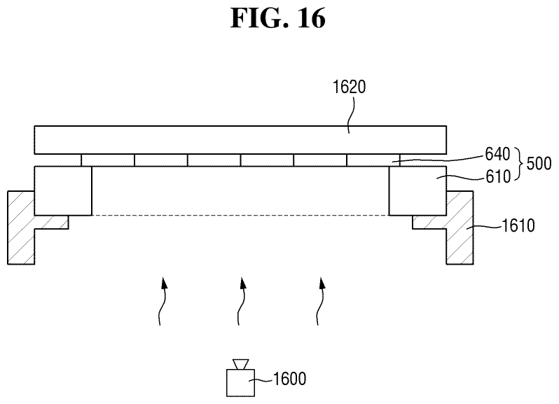

FIG. 16 is a schematic view illustrating a deposition process using a mask assembly 500 according to an embodiment.

Referring to FIG. 16, the mask assembly 500 is placed and fixed on a frame holder 1610. The frame holder 1610 may support a mask frame 610 by overlapping with at least a portion of an outer portion of the mask frame 610.

A substrate 1620 is placed on a upper surface (upper surface in the drawing) of the mask assembly 500, that is, also an upper surface of each deposition mask 640. The substrate 1620 may be a deposition target. For example, the substrate 1620 may be the substrate SUB of the display panel 10 described with reference to FIGS. 1 through 4.

A surface (lower surface in the drawing) of the substrate 1620 may be placed to face the upper surface of the deposition masks 640. For example, the surface (lower surface in the drawing) of the substrate 1620 may be placed to contact the upper surface of the deposition masks 640.

A deposition source 1600 is placed on a lower surface (lower surface in the drawing) of the mask assembly 500. For example, the deposition source 1600 may be placed to face the lower surface (lower surface in the drawing) of the mask assembly 500. The deposition source 1600 may accommodate a deposition material therein, vaporize the deposition material during the deposition process, and provide the vaporized deposition material to the substrate 1620.

The deposition material passes through the frame opening 610p of the mask frame 610 and pattern openings 642p (see FIG. 7) of the deposition masks 640. Then, the deposition material is deposited on the surface of the substrate 1620 exposed by the pattern openings 642p of the deposition masks 640, thereby forming a patterned thin-film layer. For example, the patterned thin-film layer deposited on the substrate 1620 may be at least the light emitting layers 172 described with reference to FIG. 4.

According to an embodiment, a deposition process using the mask assembly 500, for example, a method of manufacturing organic light emitting device may include the following steps. For example, the method of manufacturing the organic light emitting device may include placing the substrate 1620 on a surface of the mask assembly 500, placing the deposition source 1600 to face another surface of the mask assembly 500, vaporizing a deposition material accommodated in the deposition source 1600, and letting the vaporized deposition material pass through the mask assembly 500 and be deposited on the substrate 1620.

According to a mask assembly capable of stably supporting a deposition mask and a method of manufacturing organic light emitting device using the same according to the embodiments of the present disclosure, it is possible to enhance the precision of a deposition process by stably supporting a deposition mask.

However, the features of the present disclosure are not restricted to the one set forth herein. The above and other features of the present disclosure will become more apparent to one of daily skill in the art to which the present disclosure pertains by referencing the claims.

In concluding the detailed description, those skilled in the art will appreciate that many variations and modifications can be made to the present embodiments without substantially departing from the principles of the present inventive concept. Therefore, the disclosed present embodiments are used in a generic and descriptive sense only and not for purposes of limitation.

What is claimed is:

1. A mask assembly comprising:
a mask frame;
a plurality of first sticks disposed on the mask frame and extending in a direction parallel to first sides of the mask frame;
a plurality of second sticks disposed on the first sticks and extending in a direction parallel to second sides of the mask frame; and
deposition masks disposed on the second sticks,
wherein the second sticks comprise a first long-side stick disposed adjacent to each of the second sides of the mask frame and a second long-side stick spaced apart from the second sides of the mask frame, the first long-side stick comprises wing portions extending in the direction parallel to the first sides of the mask frame, and each of the second sides of the mask frame comprises wing grooves in which the wing portions are seated.

2. The mask assembly of claim 1, wherein each of the first sides of the mask frame comprises first grooves in which ends of the second sticks are seated, and each of the second sides of the mask frame comprises second grooves in which ends of the first sticks are seated.

3. The mask assembly of claim 2, wherein the wing grooves and the second grooves overlap each other.

4. The mask assembly of claim 3, wherein the ends of the first sticks are seated in the second grooves, and the wing portions are seated in the wing grooves which are placed on the second grooves.

5. The mask assembly of claim 4, wherein each of the wing portions comprises a first wing portion seated in a wing groove and a second wing portion disposed symmetrically to the first wing portion with respect to a direction in which the second sticks extend.

6. The mask assembly of claim 2, wherein a height of each of the second sticks is equal to a height of each of the wing grooves.

7. The mask assembly of claim 2, wherein a width of each of the wing grooves is equal to or greater than a width of each of the second grooves.

8. The mask assembly of claim 2, wherein a first length of each of the wing grooves extending from a first inner side surface of the mask frame is shorter than a second length of each of the first grooves extending from a second inner side surface of the mask frame.

9. The mask assembly of claim 1, wherein the deposition masks extend in the direction parallel to the first sides of the mask frame.

10. The mask assembly of claim 1, wherein each of the deposition masks comprises:
fixing portions positioned at both ends of the deposition mask;
at least one deposition pattern portion positioned between the fixing portions and comprising a plurality of pattern openings; and
a rib portion positioned around the deposition pattern portion.

11. A mask assembly comprising:
a mask frame;
a plurality of second sticks disposed on the mask frame and extending in a direction parallel to second sides of the mask frame;
a plurality of first sticks disposed on the second sticks and extending in a direction parallel to first sides of the mask frame; and
deposition masks disposed on the first sticks,
wherein the second sticks comprise a first long-side stick disposed adjacent to each of the second sides of the mask frame and a second long-side stick spaced apart from the second sides of the mask frame, the first long-side stick comprises wing portions extending in the direction parallel to the first sides of the mask frame, and each of the second sides of the mask frame comprises wing grooves in which the wing portions are seated.

12. The mask assembly of claim 11, wherein each of the first sides of the mask frame comprises first grooves in which ends of the second sticks are seated, and each of the second sides of the mask frame comprises second grooves in which ends of the first sticks are seated.

13. The mask assembly of claim 12, wherein the wing grooves and the second grooves overlap each other.

14. The mask assembly of claim 13, wherein the ends of the first sticks are seated in the second grooves, and the wing portions are seated in the wing grooves which are placed under the second grooves.

15. The mask assembly of claim 14, wherein each of the wing portions comprises a first wing portion seated in a wing groove and a second wing portion disposed symmetrically to the first wing portion with respect to a direction in which the second sticks extend.

16. The mask assembly of claim 12, wherein a height of each of the second sticks is equal to a height of each of the wing grooves.

17. The mask assembly of claim 12, wherein a width of each of the wing grooves is equal to or greater than a width of each of the second grooves.

18. The mask assembly of claim 12, wherein a first length of each of the wing grooves extending from a first inner side surface of the mask frame is shorter than a second length of each of the first grooves extending from a second inner side surface of the mask frame.

19. The mask assembly of claim 11, wherein the deposition masks extend in the direction parallel to the first sides of the mask frame.

20. The mask assembly of claim 11, wherein each of the deposition masks comprises:
fixing portions positioned at both ends of the deposition mask;
at least one deposition pattern portion positioned between the fixing portions and comprising a plurality of pattern openings; and
a rib portion positioned around the deposition pattern portion.

21. A method of manufacturing organic light emitting device, the method comprising:
placing a substrate on a surface of a mask assembly;
placing a deposition source to face another surface of the mask assembly; and
vaporizing a deposition material accommodated in the deposition source, and letting the vaporized deposition material pass through the mask assembly and be deposited on the substrate,
wherein the mask assembly comprises:
a mask frame;
a plurality of first sticks disposed on the mask frame and extending in a direction parallel to first sides of the mask frame;
a plurality of second sticks disposed on the first sticks and extending in a direction parallel to second sides of the mask frame; and
deposition masks disposed on the second sticks,
wherein the second sticks comprise a first long-side stick disposed adjacent to each of the second sides of the mask frame and a second long-side stick spaced apart from the second sides of the mask frame, the first long-side stick comprises wing portions extending in the direction parallel to the first sides of the mask frame, and each of the second sides of the mask frame comprises wing grooves in which the wing portions are seated.

22. The method of claim 21, wherein each of the first sides of the mask frame comprises first grooves in which ends of the second sticks are seated, and each of the second sides of the mask frame comprises second grooves in which ends of the first sticks are seated.

23. The method of claim 22, wherein the wing grooves and the second grooves overlap each other.

24. The method of claim 23, wherein the ends of the first sticks are seated in the second grooves, and the wing portions are seated in the wing grooves which are placed on the second grooves.
